(19) United States
(12) Patent Application Publication
(10) Pub. No.: US 2026/0299221 A1
(43) Pub. Date: Oct. 1, 2026

(54) OPTOELECTRONIC MODULE

(71) Applicant: ams-OSRAM International GmbH, Regensburg (DE)

(72) Inventors: Thomas SCHWARZ, Regensburg (DE); Aimi ABASS, Regensburg (DE); Farhang GHASEMI AFSHAR, Wenzenbach (DE); Juergen MOOSBURGER, Lappersdorf (DE); Laura KREINER, Regensburg (DE)

(21) Appl. No.: 19/477,044

(22) PCT Filed: Apr. 24, 2024
(86) PCT No.: PCT/EP2024/061237

§ 371 Date: Oct. 20, 2025

(30) Foreign Application Priority Data
Apr. 24, 2023 (DE) 10 2023 110 417.9

(51) Int. Cl. G02B 6/42; H10H 20/80; H10H 20/856

(52) U.S. Cl. CPC G02B 6/4214; G02B 6/4202; G02B 6/4212; G02B 6/4245; H10H 20/856; H10H 20/882

(57) ABSTRACT

An optoelectronic module comprises a photonic chip and a light-emitting diode chip. The light-emitting diode chip comprises a first face, a second face that is opposed to the first face and side faces that extend between the first face and the second face. The photonic chip comprises a waveguide. The waveguide comprises a core arranged between a lower cladding layer and an upper cladding layer. An opening is formed in the upper cladding layer. The light-emitting diode chip is arranged on the core in the opening such that the first face is oriented towards the core.

The present invention relates to an optoelectronic module.

This patent application claims the priority of German patent application 10 2023 110 417.9, the disclosure content of which is hereby incorporated by reference.

It is known in the state of the art to use lasers to couple light into a waveguide of a photonic chip.

It is an object of the present invention to provide an optoelectronic module. This objective is achieved by an optoelectronic module according to the independent claim. Preferred embodiments are disclosed in the dependent claims.

An optoelectronic module comprises a photonic chip and a light-emitting diode chip. The light-emitting diode chip comprises a first face, a second face that is opposed to the first face and side faces that extend between the first face and the second face. The photonic chip comprises a waveguide. The waveguide comprises a core arranged between a lower cladding layer and an upper cladding layer. An opening is formed in the upper cladding layer. The light-emitting diode chip is arranged on the core in the opening such that the first face is oriented towards the core.

This optoelectronic module allows to couple light emitted by the light-emitting diode chip into the waveguide of the photonic chip. A light-emitting diode chip provides the advantage over a laser chip of being smaller and more cost-efficient. Arranging the light-emitting diode chip directly on the core advantageously allows for an efficient in-coupling of the light emitted by the light-emitting diode chip.

In an embodiment of the optoelectronic module, a reflective box is formed around the light-emitting diode chip. Advantageously, the reflective box may serve to reflect light emitted by the light-emitting diode chip, which is not directly coupled into the core of the waveguide, towards the core to allow for in-coupling of the reflected light. This may increase the efficiency of the optoelectronic module.

In an embodiment of the optoelectronic module, the reflective box comprises a first polymer and a second polymer having different refractive indices. The first polymer is in contact with the side faces of the light-emitting diode chip. The second polymer is arranged around the first polymer. Advantageously, this arrangement of the first polymer and the second polymer allows to reflect light at a boundary surface between the first polymer and the second polymer.

In an embodiment of the optoelectronic module, a refractive index of the first polymer matches a refractive index of the core. A refractive index of the second polymer matches a refractive index of the upper cladding layer. Advantageously, this combination of refractive indices allows for an efficient coupling of light emitted by the light-emitting diode chip into the waveguide of the photonic chip.

In an embodiment of the optoelectronic module, a metallic mirror layer is arranged between the first polymer and the second polymer. Advantageously, providing a metallic mirror layer between the first polymer and the second polymer allows for a particularly effective reflection of light at the boundary between the first polymer and the second polymer.

In an embodiment of the optoelectronic module, the reflective box comprises a metallic mirror layer arranged on the second face and on the side faces of the light-emitting diode chip. Advantageously, a metallic mirror layer arranged on the light-emitting diode chip efficiently reflects light emitted by the light-emitting diode chip in a direction towards the core of the waveguide such that this light can be coupled into the waveguide.

In an embodiment of the optoelectronic module, a metallic mirror layer is arranged between the lower cladding layer and the core below the light-emitting diode chip. Light emitted by the light-emitting diode chip that is not coupled into the core of the waveguide can be reflected back towards the core by the metallic mirror layer. The reflected light can be coupled into the core of the waveguide after the reflection.

In an embodiment of the optoelectronic module, the opening of the upper cladding layer is at least partially filled with a polymer. This polymer may serve to replace the missing upper cladding layer in the opening such that light coupled into the core of the waveguide is effectively confined to the core of the waveguide.

In an embodiment of the optoelectronic module, the core comprises a recess. The light-emitting diode chip is arranged in the recess. This arrangement may help to increase the amount of light emitted by the light-emitting diode chip that is coupled into the waveguide.

In an embodiment of the optoelectronic module, the core comprises a contact section having an extended width with respect to neighbouring sections of the core. The light-emitting diode chip is arranged on the contact section of the core. Advantageously, this allows to use a light-emitting diode chip having a width that is larger than the width of most sections of the core.

In an embodiment of the optoelectronic module, a reflective structure is arranged on a side of the upper cladding layer that is opposed to the core in a vicinity of the light-emitting diode chip. The reflective structure may serve to reflect light emitted by the light-emitting diode chip, that is not yet coupled into the waveguide, back to the core of the waveguide such that this light can be coupled into the core of the waveguide after the reflection.

In an embodiment of the optoelectronic module, the reflective structure comprises a micro structure. A reflective structure designed as a micro structure may allow for an effective re-flection of light.

In an embodiment of the optoelectronic module, electrical contacts of the light-emitting diode chip are arranged on the second face. Advantageously, this allows to connect the light-emitting diode chip in an easy way.

In an embodiment of the optoelectronic module, the first face of the light-emitting diode chip diode chip comprises a rectangular shape. Oblong sides of the first face are oriented parallel to a longitudinal direction of the waveguide. Advantageously, this allows the first face of the light-emitting diode chip to comprise an extended size even at a limited width.

In an embodiment of the optoelectronic module, the side faces of the light-emitting diode chip are inclined at an angle different from 90° with respect to the first face. Advantageously, this may increase the amount of light emitted by the light-emitting diode chip that can be coupled into the waveguide.

In an embodiment of the optoelectronic module, a glue is arranged between the core and the first face of the light-emitting diode chip. The glue may have a refractive index that is adapted to the refractive indices of the light-emitting diode chip and the core.

In an embodiment of the optoelectronic module, the glue comprises scattering particles. Scattering particles embedded in the glue may increase the efficiency of the coupling of the light emitted by the light-emitting diode chip into the waveguide.

The above-described properties, features and advantages of the invention, as well as the way in which they are achieved, will become more clearly and comprehensively understandable in connection with the following description of exemplary embodiments, which will be explained in more detail in connection with the drawings in which, in schematic representation:

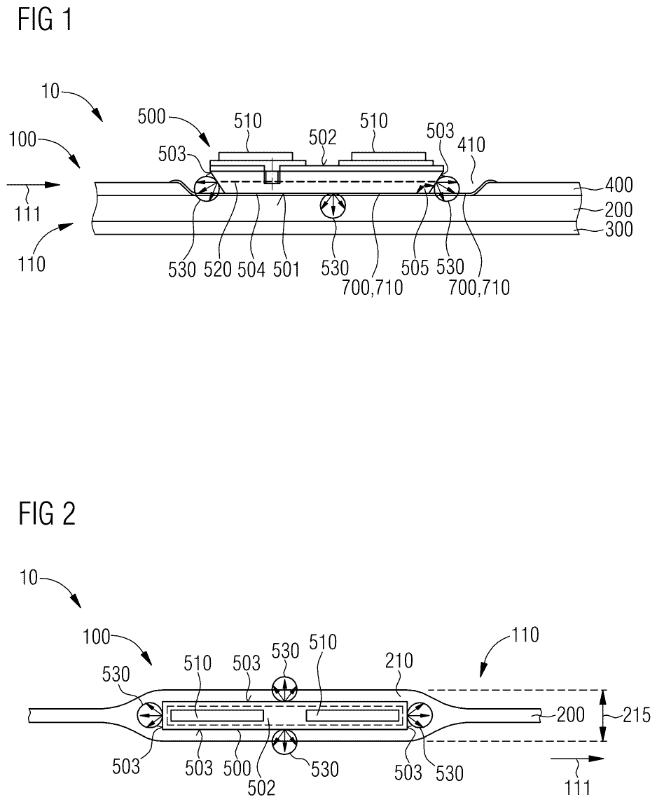

FIG. 1 shows a sectional view of parts of a variant of an optoelectronic module;

FIG. 2 shows a top-view of the optoelectronic module;

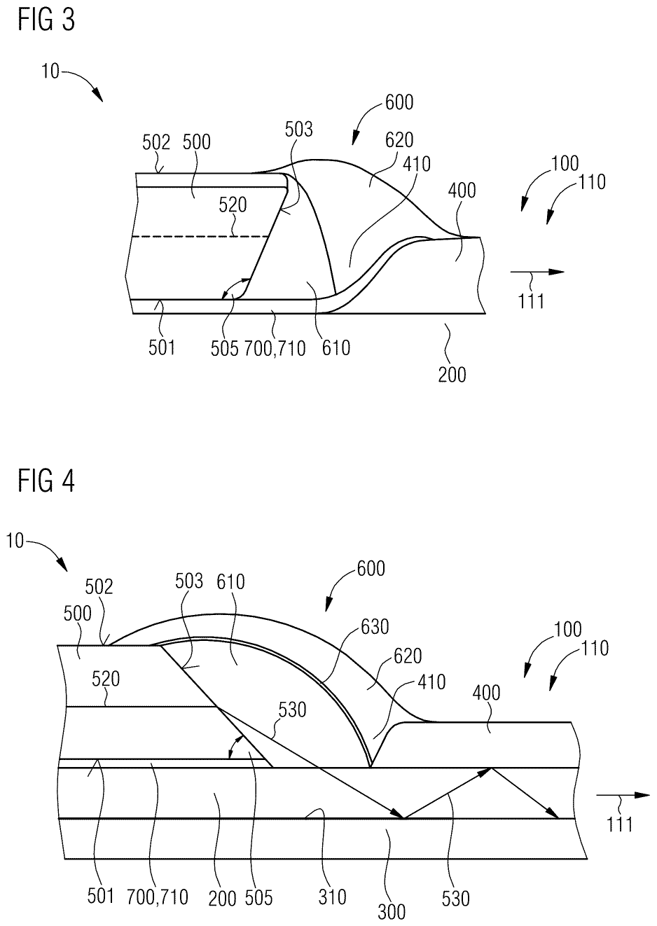

FIG. 3 shows a sectional view of parts of a variant of an optoelectronic module;

FIG. 4 shows a sectional view of parts of a variant of an optoelectronic module;

FIG. 5 shows a sectional view of parts of a variant of an optoelectronic module;

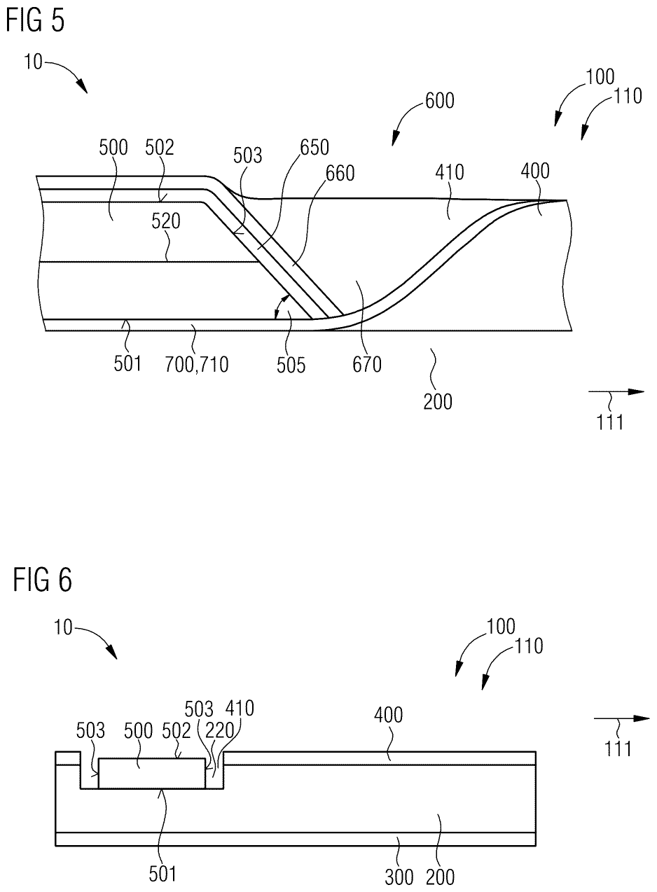

FIG. 6 shows a sectional view of parts of a variant of an optoelectronic module; and

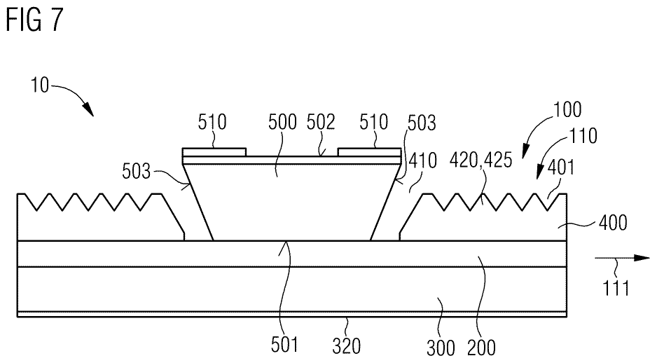

FIG. 7 shows a section view of parts of a variant of an optoelectronic module.

FIG. 1 shows a schematic sectional view of a variant of an optoelectronic module 10. For simplicity, not all components of the optoelectronic module 10 are depicted. FIG. 2 shows a schematic top-view of the same optoelectronic module 10.

The optoelectronic module 10 comprises a photonic chip 100. The photonic chip 100 may also be referred to as a photonic integrated circuit. The photonic chip 100 comprises a waveguide 110 that extends along a longitudinal direction 111. The waveguide 110 comprises a core 200 arranged between a lower cladding layer 300 and an upper cladding layer 400. The upper cladding layer 400 is not visible in FIG. 2.

The lower cladding layer 300 and the upper cladding layer 400 typically comprise a refractive index that is smaller than a refractive index of the core 200.

As shown in FIG. 1, the upper cladding layer 400 comprises an opening 410 where the upper cladding layer 400 has been removed to expose the core 200.

The optoelectronic module 10 comprises a light-emitting diode chip 500. The light-emitting diode chip 500 has a first face 501, a second face 502 which is opposed to the first face 501, and four side faces 503 which extend between the first face 501 and the second face 502.

In the example depicted in FIGS. 1 and 2, the light-emitting diode chip 500 comprises of only epitaxial layers. A growth substrate has been removed. In other variants, however, the light-emitting diode chip 500 may comprise a growth substrate or another carrier substrate.

The light-emitting diode chip 500 is designed to emit light 530, for example visible light. The light 530 is emitted at the first face 501 and at the side faces 503. A mirror layer may be arranged at the second face 502 such that no light is emitted at the second face 502 of the light-emitting diode chip 500. Internally, the light 530 is generated in an active layer 520 of the light-emitting diode chip 500.

The light-emitting diode chip 500 comprises a plurality of electrical contacts 510 for providing the light-emitting diode chip 500 with electrical voltage and electrical current. In the example depicted in FIGS. 1 and 2, the electrical contacts 510 are arranged at the second face 502 of the light-emitting diode chip 500.

The light-emitting diode chip 500 is arranged on the core 200 of the waveguide 110 in the opening 410 formed in the upper cladding layer 400. The first face 501 of the light-emitting diode chip 500 is oriented towards the core 200. This arrangement serves to couple at least parts of the light 530 emitted by the light-emitting diode chip 500 into the core 200 of the waveguide 110.

The light-emitting diode chip 500 is attached to the core 200 using a glue 700. The glue 700 is arranged between the core 200 and the first face 501 of the light-emitting diode chip 500. The glue 700 may also cover the remaining surface of the core 200 that is exposed in the opening 410 of the upper cladding layer 400 and may also extend onto the upper cladding layer 400. Expediently, a refractive index of the glue 700 is adjusted to the refractive indices of the light-emitting diode chip 500 and the core 200. The glue 700 may comprise a refractive index with a value between those of the light-emitting diode chip 500 and the core 200, for example.

In some variants of the optoelectronic module 10, the glue 700 may be replaced by another attachment material. In one example, porous GaN is used to attach the light-emitting diode chip 500 to the core 200.

The glue 700 may comprise embedded scattering particles 710. Scattering particles 710 may be provided to scatter light 530 emitted by the light-emitting diode chip 500 to change an angular distribution of the light 530. This may increase the amount of light 530 that is successfully coupled into the core 200 of the waveguide 110. The scattering particles 710 may be omitted, however.

The first face 501 of the light-emitting diode chip 500 may comprise a roughening, for example a roughening on a micrometre scale. The roughening may support coupling light 530 out of the light-emitting diode chip 500 at the first face 501. Alternatively, or additionally, the surface of the core 200 that is exposed in the opening 410 may comprise a roughening, for example a roughening on a micrometre scale. A roughening of the surface of the core 200 may support coupling light 530 into the core 200.

FIG. 2 shows that the core 200 comprises a contact section 210. A width 215 of the core 200, measured in a direction perpendicular to the longitudinal direction 111 of the waveguide 110, is larger in the contact section 210 than in neighbouring sections of the core 200. At least a part of the contact section 210 is exposed in the opening 410 of the upper cladding layer 400. The light-emitting diode chip 500 is arranged on the contact section 210 of the core 200. The contact section 210 having an extended width 215 allows the first face 501 of the light-emitting diode chip 500 to comprise a width that is larger than the width 215 of the core 200 in sections outside of the contact section 210. In case that the extended width 215 of the contact section 210 is not required, the contact section 210 may comprise the same width 215 as the other sections of the core 200.

In the example depicted in FIGS. 1 and 2, the first face 501 of the light-emitting diode chip 500 comprises a rectangular shape. Oblong sides 504 of the first face 501 are oriented parallel to the longitudinal direction 111 of the waveguide 110. This way, the shape of the light-emitting diode chip 500 and its first face 501 is optimized for being arranged on the long and narrow surface of the core 200. The first face 501 of the light-emitting diode chip 500 may comprise a size of 1 μm×10 μm or 10 μm×100 μm, for example. In other variants, however, the first face 501 of the light-emitting diode chip 500 may have other dimensions or another shape like a square shape, for example.

FIG. 1 shows that the side faces 503 of light-emitting diode chip 500 are inclined at an angle 505 with respect to the first face 501. In the example shown in FIG. 1, the angle 505 is larger than 90° such that the side faces 503 are oriented towards the core 200. This is also the case in the examples of FIGS. 3 and 7 explained below. In other variants, however, the angle 505 may be smaller than 90°, such that the side faces 503 of the light-emitting diode chip 500 are oriented away from the core 200. This is the case in the examples shown in FIGS. 4 and 5 which will be explained below. The angle 505 may be equal to 90° as well, as it is shown in the example of FIG. 6. In all variants of the optoelectronic module 10, the angle 505 should be chosen such that a maximum of the light 530 that is emitted at the side faces 503 of the light-emitting diode chip 500 is coupled into the core 200 of the waveguide 110.

In the following, with reference to FIGS. 3 to 5, variants of the optoelectronic module 10 will be explained which complement the variant shown in FIGS. 1 and 2 with a reflective box 600 that is formed around the light-emitting diode chip 500.

In the variant of the optoelectronic module 10 shown in FIG. 3, the reflective box 600 comprises a first polymer 610 and a second polymer 620. The first polymer 610 is arranged in the opening 410 of the upper cladding 400 around the light-emitting diode chip 500 and is in contact with the side faces 503 of the light-emitting diode chip 500. The second polymer 520 is arranged around the first polymer 610 and is in contact with the first polymer 610. The second polymer 620 is also at least partially arranged in the opening 410 of the upper cladding layer 400. This way, the opening 410 of the upper cladding layer 400 is at least partially filled with the first polymer 610 and the second polymer 620.

The first polymer 610 and the second polymer 620 have different refractive indices. It is convenient, if the first polymer 610 comprises a larger refractive index than the second polymer 620. In one example, the refractive index of the first polymer 610 matches a refractive index of the core 200 and the refractive index of the polymer 620 matches a refractive index of the upper cladding layer 400.

In the example shown in FIG. 3, the glue 700 that is arranged between the core 200 and the first face 510 of the light-emitting diode chip 500 is also arranged between the core 200 and the first polymer 610 and between the upper cladding layer 400 and the second polymer 620. It may, however, be more convenient if the second polymer 620 is in direct contact with the upper cladding layer 400 and the first polymer 610 is in direct contact with the core 200.

Light 530, emitted at the side faces 503 of the light-emitting diode chip 500, may be reflected at a boundary surface between the first polymer 610 and the second polymer 620 by total internal reflection. Light 530 reflected at said boundary surface may be directed towards the core 200 such that it can be coupled into the core 200.

The boundary surface between the first polymer 610 and the second polymer 620 comprises a shape that is chosen such that a large proportion of light emitted at the side faces 503 of the light-emitting diode chip 500 is reflected at an angle that allows coupling into the core 200 of the waveguide 110.

FIG. 4 shows a variant of the optoelectronic module 10 that is similar to the variant shown in FIG. 3. In addition to the features described in conjunction with FIG. 3, the variant shown in FIG. 4 comprises a metallic mirror layer 630 arranged between the first polymer 610 and the second polymer 620. The metallic mirror layer 630 serves to reflect light 530 emitted at the side faces 503 of the light-emitting diode chip 500 towards the core 200 such that the reflected light 530 can be coupled into the core 200 of the waveguide 110. Compared to the variant of the optoelectronic module 10 shown in FIG. 3, the metallic mirror layer 630 may also reflect light 530 that hits at an angle outside of the angular range that undergoes total internal reflection.

The optoelectronic module 10 of FIG. 4 additionally comprises a metallic mirror layer 310 arranged between the lower cladding layer 300 and the core 200 below the light-emitting diode chip 500. This metallic mirror layer 310 may serve to reflect light 530 that reaches the core 200 at an incident angle outside of the angular range that is accepted by the core 200 and thus passes through the core 200. Light 530 reflected at the metallic mirror layer 310 obtains another chance to couple into the core 200 of the waveguide 110. It is convenient if the metallic mirror layer 310 is larger than the light-emitting diode chip 500 in the longitudinal direction 111.

The optoelectronic module 10 shown in FIG. 4 further differs from the variant shown in FIG. 3 in that the angle 505 between the first face 501 and the side faces 503 of the light-emitting diode chip 500 is smaller than 90°. This angle 505 may allow parts of the light 530 emitted at the side faces 503 of the light-emitting diode chip 500 to be refracted towards the core 200 in the first polymer 610 such that this light 530 directly couples into the core 200 of the waveguide 110.

A further difference between FIGS. 3 and 4 is that in the variant of the optoelectronic module 10 shown in FIG. 4, the glue 700 is only arranged between the core 200 and the light-emitting diode chip 500 but not below the first polymer 610 and the second polymer 620.

In further variants of the optoelectronic module 10, the variant of the optoelectronic module 10 shown in FIG. 3 can be complemented with one or several of the additional features described in conjunction with FIG. 4 above.

FIG. 5 shows a variant of the optoelectronic module 10 where the reflective box 600 comprises a metallic mirror lay-er 660 arranged on the second face 502 and the side faces 503 of the light-emitting diode chip 500. A passivation layer 650 may be arranged between the second face 502 and the side faces 503 below the metallic mirror layer 660 to prevent electric short circuits. The metallic mirror layer 660 may be referred to as a Monte Bianco mirror. The metallic mirror layer 660 serves to reflect light 530 emitted at the second face 502 and the side faces 503 towards the core 200 such that reflected light can be coupled into the core 200 of the waveguide 110.

A polymer 670 is arranged around the light-emitting diode chip 500 in the opening 410 of the upper cladding layer 400 to fill the opening 410 at least partially. The polymer 670 may comprise a refractive index that matches the refractive index of the upper cladding layer 400, for example, and may serve to complete the upper cladding layer 400. The polymer 670 may be omitted.

In the example shown in FIG. 5, the glue 700 that is arranged between the core 200 and the light-emitting diode chip 500 is also arranged between the polymer 670 and the upper cladding layer 400. It is possible, however, to omit the glue 700 in that area such that the polymer 670 is in direct contact with the upper cladding layer 400.

FIG. 6 shows a schematic sectional view of a further variant of the optoelectronic module 10. In this variant, the core 200 comprises a recess 220 where a part of the material of the core 200 has been removed. The recess 220 adjoins the opening 410 of the upper cladding layer 400. The light-emitting diode chip 500 is arranged in the recess 220. In this way, at least some parts of the light 530 that is emitted at the side faces 503 of the light-emitting diode chip 500 directly hits the core 200 and can be coupled into the core 200.

The optoelectronic module 10 shown in FIG. 6 may be complemented with a reflective box 600 as described in conjunction with FIGS. 3 to 5 and may also comprise any of the additional features described above with reference to FIGS. 1 to 5.

FIG. 7 shows a variant of the optoelectronic module 10 that is similar to the variant described in conjunction with FIGS. 1 and 2. The variant of FIG. 7 additionally comprises a reflective structure 420 arranged on an upper side 401 of the upper cladding layer 400. The upper side 401 of the upper cladding layer 400 is opposed to the side of the upper cladding layer 400 that is in contact with the core 200. The reflective structure 420 is arranged in the vicinity of the light-emitting diode chip 500 around the opening 410 of the upper cladding layer 400.

The reflective structure 420 may serve to reflect light 530 emitted by the light-emitting diode chip 500 towards the core 200 such that the reflected light 530 can be coupled into the core 200 of the waveguide 110. The reflective structure 420 may serve to reflect light 530 that hits the reflective structure 420 inside the upper cladding layer 400 but may also serve to reflect or deflect light 530 that hits the reflective structure 420 from outside of the upper cladding layer 400 such that the reflected or deflected light is directed towards the core 200. The reflective structure 420 may comprise a microstructure 425, for example.

The optoelectronic module 10 of FIG. 7 additionally comprises a metallic mirror layer 320 arranged on a side of the lower cladding layer 300 that is opposed to the side of the lower cladding layer 300 that is in contact with the core 200. The metallic mirror layer 320 serves to reflect light 530 which is not yet coupled into the core 200 of the waveguide 110 towards the core 200 such that it obtains another to chance to couple into the core 200 of the waveguide 110.

In an alternative variant, the metallic mirror layer 320 may be arranged between the lower cladding layer 300 and the core 200 as the metallic mirror layer 310 shown in FIG. 4.

The optoelectronic module 10 shown in FIG. 7 may be complemented with a reflected box 600 as described in conjunction with FIGS. 3 to 5 and may also comprise any of the additional features explained above with reference to FIGS. 1 to 6.

The invention has been illustrated and described in more detail with the aid of the preferred exemplary embodiments. The invention is not, however, restricted to the examples disclosed. Rather, other variants may be derived therefrom by the person skilled in the art.

### REFERENCE SYMBOLS

10 optoelectronic module
100 photonic chip
110 waveguide
111 longitudinal direction
200 core
210 contact section
215 width
220 recess
300 lower cladding layer
310 metallic mirror layer
320 metallic mirror layer
400 upper cladding layer
401 upper side
410 opening
420 reflective structure
425 microstructure
500 light-emitting diode chip
501 first face
502 second face
503 side face
504 oblong side
505 angle
510 electrical contact
520 active layer
530 light
600 reflective box
610 first polymer
620 second polymer
630 metallic mirror layer
650 passivation layer
660 metallic mirror layer
670 polymer
700 glue
710 scattering particles

1.-17. (canceled)

18. An optoelectronic module
comprising a photonic chip and a light-emitting diode chip,
wherein the light-emitting diode chip comprises a first face, a second face that is opposed to the first face, and side faces that extend between the first face and the second face,
wherein the photonic chip comprises a waveguide,
wherein the waveguide comprises a core arranged between a lower cladding layer and an upper cladding layer,
wherein an opening is formed in the upper cladding layer,
wherein the light-emitting diode chip is arranged on the core in the opening such that the first face is oriented towards the core,
wherein a reflective box is formed around the light-emitting diode chip,
wherein the reflective box comprises a first polymer and a second polymer having different refractive indices,
wherein the first polymer is in contact with the side faces of the light-emitting diode chip,
wherein the second polymer is arranged around the first polymer.

19. The optoelectronic module according to claim 18,
wherein a refractive index of the first polymer matches a refractive index of the core,
wherein a refractive index of the second polymer matches a refractive index of the upper cladding layer.

20. The optoelectronic module according to claim 18,
wherein a metallic mirror layer is arranged between the first polymer and the second polymer.

21. The optoelectronic module according to claim 18,
wherein a metallic mirror layer is arranged between the lower cladding layer and the core below the light-emitting diode chip.

22. The optoelectronic module according to claim 18,
wherein the opening of the upper cladding layer is at least partially filled with a polymer.

23. The optoelectronic module according to claim 18,
wherein the core comprises a recess,
wherein the light-emitting diode chip is arranged in the recess.

24. The optoelectronic module according to claim 18,
wherein the core comprises a contact section having an ex-tended width with respect to neighbouring sections of the core,
wherein the light-emitting diode chip is arranged on the contact section of the core.

25. The optoelectronic module according to claim 18,
wherein a reflective structure is arranged on a side of the upper cladding layer that is opposed to the core in a vicinity of the light-emitting diode chip.

26. The optoelectronic module according to claim 25,
wherein the reflective structure comprises a microstructure.

27. The optoelectronic module according to claim 18,
wherein electrical contacts of the light-emitting diode chip are arranged on the second face.

28. The optoelectronic module according to claim 18,
wherein the first face of the light-emitting diode chip comprises a rectangular shape,
wherein oblong sides of the first face are oriented parallel to a longitudinal direction of the waveguide.

29. The optoelectronic module according to claim 18,
wherein the side faces of the light-emitting diode chip are inclined at an angle different from 90° with respect to the first face.

30. The optoelectronic module according to claim 18,
wherein a glue is arranged between the core and the first face of the light-emitting diode chip.

31. The optoelectronic module according to claim 30,
wherein the glue comprises scattering particles.

32. An optoelectronic module
comprising a photonic chip and a light-emitting diode chip,
wherein the light-emitting diode chip comprises a first face, a second face that is opposed to the first face, and side faces that extend between the first face and the second face,
wherein the photonic chip comprises a waveguide,
wherein the waveguide comprises a core arranged between a lower cladding layer and an upper cladding layer,
wherein an opening is formed in the upper cladding layer,
wherein the light-emitting diode chip is arranged on the core in the opening such that the first face is oriented towards the core,
wherein a reflective box is formed around the light-emitting diode chip, wherein the reflective box comprises a metallic mirror lay-er arranged on the second face and the side faces of the light-emitting diode chip.
